(19) United States
(12) Patent Application Publication
(10) Pub. No.: US 2009/0051442 A1
(43) Pub. Date: Feb. 26, 2009

(54) TRANSIMPEDANCE AMPLIFIER CIRCUIT FOR OPTICAL RECEIVER IN OPTICAL COMMUNICATION SYSTEM

(76) Inventors: Ja-Won SEO, Gyeonggi-do (KR); Yun Ah SIM, Seongnam-si (KR); Sang-Gug LEE, Daejeon (KR)

Correspondence Address: CHA & REITER, LLC, 210 ROUTE 4 EAST STE 103, PARAMUS, NJ, 07652, US

(21) Appl. No.: 12/193,984

(22) Filed: Aug. 19, 2008

(30) Foreign Application Priority Data
Aug. 22, 2007 (KR) 2007-0084657

(51) Int. Cl. H03F 3/08

(52) U.S. Cl. 330/308

(57) ABSTRACT

A transimpedance amplifier circuit for an optical receiver in an optical communication system in which a range of an increase/decrease in bandwidth according to gain change is reduced by a bandwidth adjustor. The circuit includes: a photodiode (PD) for generating a current signal by photoelectric conversion of an input optical signal; a Transimpedance Amplifier (TIA) for converting the current signal input from the photodiode into a voltage signal; an auto gain adjustor for adjusting feedback resistances of the transimpedance amplifier; a photodiode parallel capacitor reducer for reducing a parallel capacitor current of the photodiode; and a bandwidth adjustor for reducing a range of an increase/decrease in bandwidth according to an increase/decrease in gain of the transimpedance amplifier.

### CLAIM OF PRIORITY

This application claims the benefit under 35 U.S.C. §119(a) of an application entitled “Transimpedance Amplifier Circuit for Optical Receiver in Optical Communication System” filed in the Korean Intellectual Property Office on Aug. 22, 2007 and assigned Serial No. 2007-84657, the contents of which are hereby incorporated by reference in its entirety.

### BACKGROUND OF THE INVENTION

1. Field of the Invention

The present invention relates to an optical communication system. More particularly, the present invention relates to a circuit design of a transimpedance amplifier for amplifying an output current of a light-receiving element in an optical receiver for optical communication.

2. Description of the Related Art

Generally, a communications system in which signals are transmitted through a light-emitting element, such as a laser diode, and received through a light-receiving element, such as a photodiode, is generally referred to as an optical communication system. The optical communication system is suitable for transmitting large-capacity data such as broadcast signals. As a typical example of the optical communication system, there is the Passive Optical Network (PON). The passive optical network forms a distributed topology in a tree structure by positioning an optical splitter between an Optical Line Terminal (OLT) and a plurality of Optical Network Terminations (ONTs).

In the passive optical network, the OLT, for example, converts analog and/or digital broadcast signals into optical signals having predetermined wavelengths and multiplexes the optical signals in order to transmit them to the optical splitter. In turn, the optical splitter transmits the optical signals received from the OLT, and distributes them among the multiple ONTs. The received optical signals are subjected to photoelectric conversion to analog and/or digital broadcast signals by the multiple ONTs, and are transmitted to set top boxes or computers of each subscriber.

Here, generally the optical receiver in the ONT, that is, a photoelectric converter, detects intensities of optical signals in order to adjust output levels to be stable while the optical signals received from the OLT are subjected to photoelectric conversion, and includes a gain adjusting circuit for adjusting gains of the photoelectrically converted output signals according to the intensities of the detected optical signals.

FIG. 1 shows a circuit structure diagram of the gain adjusting device included in the optical receiver of a general optical communication system, for example, illustrating a variable gain amplifying circuit for adjusting a resistance value of feedback resistances R1, R2, and R3 in a step-by-step manner according to the detected intensities of the received optical signals. The device in FIG. 1 is disclosed in U.S. Pat. No. 6,462,327, entitled “Analog Optical Receiver and Variable Gain Transimpedance Amplifier Useful Therewith,” filed by Ezell et al. on Sep. 27, 2001, and a schematic structure is described as follows:

Referring now to FIG. 1, the circuit includes: a transimpedance amplifier 101 for converting a received optical signal into a voltage signal; multiple feedback resistances R1, R2, and R3 connected in parallel between an input stage and an output stage 103 of the transimpedance amplifier 101 for adjusting a gain of the transimpedance amplifier 101 in a step-by-step manner; and multiple buffer amps 105, 107, and 109 connected between the output of the transimpedance amplifier 101 and the multiple feedback resistances R1, R2, and R3 respectively, and switched on/off according to predetermined control signals (ENABLE).

As shown in FIG. 1, after the feedback resistances R1, R2, and R3 for adjusting a gain of the transimpedance amplifier 101 are connected in parallel, if the control signals are selectively applied to the buffer amps 105, 107, and 109 respectively, a resistance value of a sum of the feedback resistances R1, R2, and R3 can be changed by selectively switching on or off the buffer amps 105, 107, and 109. As a result, an output gain of the transimpedance amplifier 101 is adjusted according to the resistance value of the feedback resistances R1, R2, and R3. For example, when the control signals are applied to only two buffer amps R1 105 and R3 109 in order to electrically connect, and other buffer amps are in an off state, the line connected with the resistance R2 and the buffer amp 107 has an infinite resistance value, so that a gain of the transimpedance amplifier 101 is determined by the resistance value of R1 and R3 in parallel.

However, since the gain adjusting device of FIG. 1 adjusts a gain by using a resistance value of a sum of multiple feedback resistances, gain adjustment is discrete. That is, the number of steps of gain adjustment is determined in proportion to the number of the feedback resistances. However, if the number of the feedback resistances is increased a certain resistance values in order to increase the steps of gain adjustment, the number of the buffer amps is also increased in proportion to this increase, and the number of additional circuits (not shown) for generating control signals is also increased in proportion as well. Thus, there are many restrictions in continuous (linear) gain adjustment according to intensities of the optical signals.

Further, in order to generate the control signals applied to the buffer amps, the gain adjusting device must include a separate circuit for detecting an amplitude of an input optical signal from an output voltage of the transimpedance amplifier, and handling the amplitude, and must control the on/off states of the buffer amps according to the handling result. However, in this case, since circuitry is complicated and requires high accuracy, there is difficulty in that the amplitude of circuitry generating control signals is increased in proportion to the number of gain adjusting steps in order to further divide gain adjusting steps.

Further, a transimpedance amplifier gain is determined by the value of feedback resistances, and as a result, the bandwidth of the transimpedance amplifier is also changed. Therefore, in light of the principle that the product of a bandwidth and a gain is constant, when a total value of feedback resistances becomes large, the gain becomes large, and as a result, the bandwidth becomes small, and on the contrary, when a total value of feedback resistances becomes small, the gain becomes small, and as a result, the bandwidth becomes large.

Accordingly, there has been a need in the art for a design of a transimpedance amplifier stably operated by solving the above-mentioned problems and by reducing the rate of an increase/decrease in bandwidth according to an increase/decrease in gain.

### SUMMARY OF THE INVENTION

Accordingly, the present invention has been made to provide a method of reducing the number of parallel capacitors of a transimpedance amplifier circuit and a photodiode in order to stably operate. In one example, the invention is achieved by reducing a combination of feedback resistances of the transimpedance amplifier, and by reducing the rate of an increase/decrease in bandwidth according to an increase/decrease in gain.

In accordance with an exemplary aspect of the present invention, there is provided a transimpedance amplifier circuit for an optical receiver in an optical communication system, including: a photodiode (PD) for generating a current signal by photoelectric conversion of an input optical signal; a Transimpedance Amplifier (TIA) for converting the current signal input from the photodiode into a voltage signal; an auto gain adjustor for adjusting feedback resistances of the transimpedance amplifier; a photodiode parallel capacitor reducer for reducing a parallel capacitor current of the photodiode; and a bandwidth adjustor for reducing a range of an increase/decrease in bandwidth according to an increase/decrease in gain of the transimpedance amplifier.

In addition, the auto gain adjustor may include: a bottom-hold circuit connected to an output stage of the transimpedance amplifier and detecting a low level of an output signal of the transimpedance amplifier; a comparator having two input stages, which receives an output signal of the bottom-hold circuit to an inverted (−) input stage and compares the received output signal with a reference voltage Vref provided to a non-inverted (+) input stage,; a fourth resistance and a fifth resistance connected in parallel to the transimpedance amplifier, respectively; and a sixth transistor connected in series to the fourth resistance and performing a switching operation of the fourth resistance according to an output signal of the comparator.

In addition, the photodiode parallel capacitor reducer may include: a first capacitor connected in series to an anode terminal of the photodiode; a third resistance connected in series to the first capacitor; and a fourth transistor whose collector terminal is connected to a power source, whose base terminal is connected to between the first capacitor and a third resistance, and whose emitter terminal is connected to a cathode terminal of the photodiode.

In addition, the bandwidth adjustor may include: a first transistor to be switched according to the Output signal of the comparator; and a second transistor, a third transistor, and a fifth transistor, which constitute a current mirror circuit.

### BRIEF DESCRIPTION OF THE DRAWINGS

The above and other aspects, features and advantages of the present invention will be more apparent from the following detailed description taken in conjunction with the accompanying drawings, in which:

FIG. 1 is a circuit structure diagram illustrating a gain adjusting device included in an optical receiver of a conventional optical communication system;

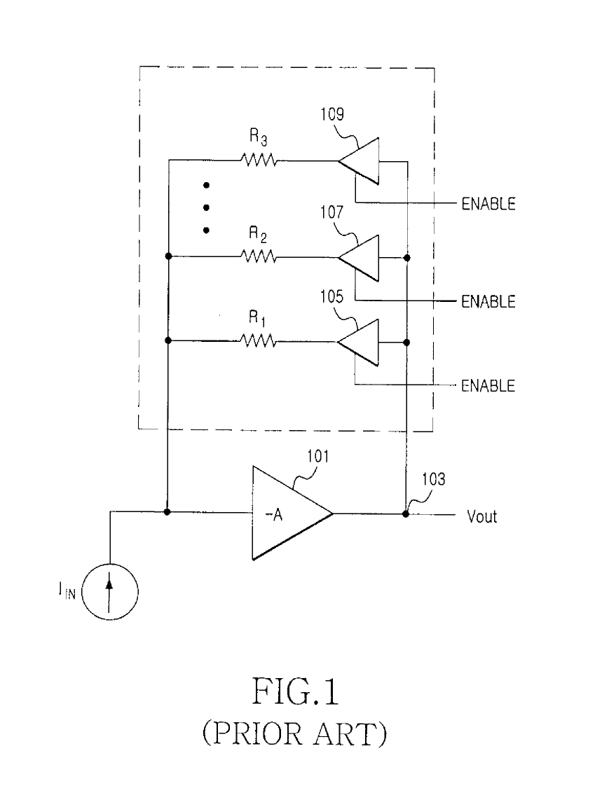

FIG. 2 is a circuit structure diagram illustrating a transimpedance amplifier for an optical receiver according to an exemplary embodiment of the present invention;

FIG. 3 is a circuit structure diagram illustrating a transimpedance amplifier for an optical receiver according to another exemplary embodiment of the present invention; and

FIG. 4 is a circuit structure diagram illustrating an equivalent circuit of transimpedance amplifier circuit for an optical receiver according to an exemplary embodiment of the present invention.

### DETAILED DESCRIPTION

Hereinafter, devices and operations according to exemplary embodiments of the present invention will be described with reference to the accompanying drawings. For the purposes of clarity and simplicity, a detailed description of known functions and configurations incorporated herein may be omitted so as not to obscure appreciation of the subject matter of the present invention by a person of ordinary skill in the art.

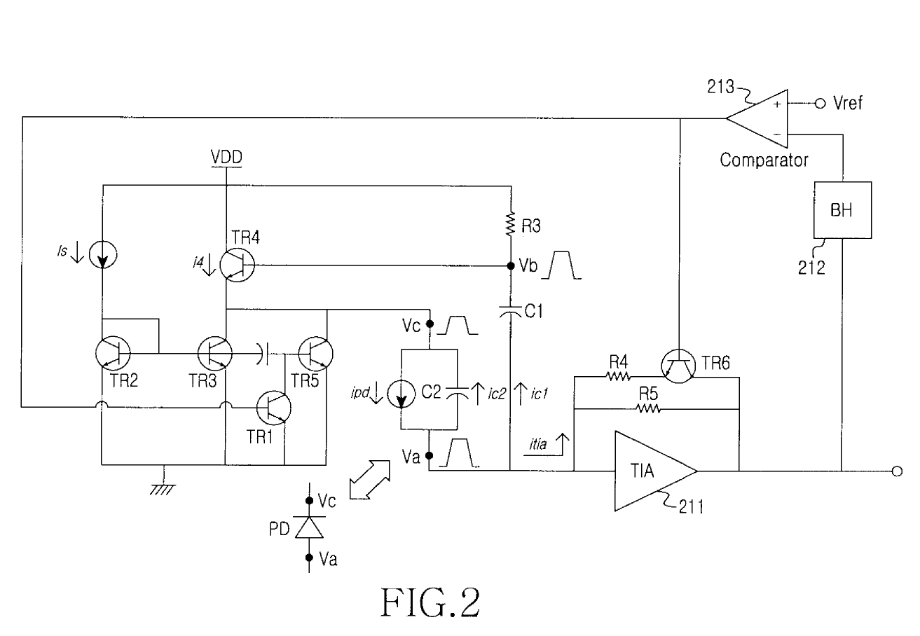

FIG. 2 shows a circuit structure diagram illustrating a transimpedance amplifier for an optical receiver according to an exemplary embodiment of the present invention. The transimpedance amplifier for an optical receiver according to the this example includes: a photodiode (PD) for generating a current signal by photoelectric conversion of an input optical signal; a Transimpedance Amplifier (TIA) 211 for converting the current signal input from the photodiode into a voltage signal; an auto gain adjustor for adjusting feedback resistances of the transimpedance amplifier 211; a photodiode parallel capacitor reducer for reducing a parallel capacitor current of the photodiode; and a bandwidth adjustor for reducing a range of an increase/decrease in bandwidth according to an increase/decrease in gain of the transimpedance amplifier.

Referring to FIG. 2, the photodiode is expressed as an equivalent circuit, meaning that the photodiode can be expressed as a current source ipd generating current output from the photodiode and a second capacitor C2 connected in parallel to the current source ipd.

The auto gain adjustor may include: a Bottom-Hold (BH) circuit 212 connected to an output stage of the transimpedance amplifier 211 and detecting a low level of an output signal of the transimpedance amplifier 211; a comparator 213 having two input stages, which receives an output signal of the bottom-hold circuit 212 to a −input stage and a reference voltage Vref to a +input stage, and comparing two signals; a fourth resistance R4 and a fifth resistance R5 connected in parallel to the transimpedance amplifier 211, respectively; and a sixth transistor TR6 connected in serial to the fourth resistance and performing a switching operation of the fourth resistance according to an output signal of the comparator 213.

The photodiode parallel capacitor reducer may include: a first capacitor C1 connected in serial to an anode terminal of the photodiode; a third resistance R3 connected in serial to the first capacitor; and a fourth transistor TR4 whose collector terminal is connected to a power source, whose base terminal is connected to between the first capacitor and the third resistance, and whose emitter terminal is connected to a cathode terminal of the photodiode.

The bandwidth adjustor of the transimpedance amplifier 211 includes: a first transistor TR1 that is switched according to the output signal of the comparator 213; and a second transistor TR2, a third transistor TR3, and a fifth transistor TR5, which constitute a current mirror circuit.

Operations of the above-mentioned transimpedance amplifier circuit will now be described with reference to the exemplary structure of the transimpedance amplifier circuit.

A gain of the transimpedance amplifier 211 is determined by its feedback resistance value. That is, when fixed feedback resistances are used, if an input optical signal is overloaded, generally, the output signal of the transimpedance amplifier 211 exceeds an available input range of the Limiting Amplifier (LA), which is the next stage of the transimpedance amplifier 211, so that distortion of the final output signal may occur. Therefore, when a large optical signal is input, it is necessary to reduce the gain by reducing a feedback resistance of the transimpedance amplifier 211.

In this way, according to the present invention, an envelope of the signal is detected by using the bottom-hold circuit 212 at the output of the transimpedance amplifier 211 because an output of the transimpedance amplifier 211 having (−) gain is generally lower than a DC state when a signal is input. That is, as an amplitude of an input optical signal becomes larger, a voltage value detected by the bottom-hold circuit 212 becomes smaller. Therefore, when an amplitude of the detected signal is smaller than a predetermined comparison voltage Vref, the comparator outputs Logic ‘High’, so that a sixth transistor TR6 used as a switch is turned ‘ON’. As a result, since a fourth resistance and a fifth resistance are connected in parallel, the resistance value of the total feedback resistances becomes a resistance value of the two resistances connected in parallel, and thus becomes reduced. On the contrary, when an amplitude of an input optical signal is small, on the same principle as the above description, the sixth transistor TR6 is turned ‘OFF’, so that the total feedback resistance becomes the fifth resistance.

In summary, with reference to FIG. 2, when a small optical signal is input, a gain becomes the fifth resistance, and when a large optical signal is input, a gain becomes a resistance value of the fourth resistance and the fifth resistance connected in parallel, so that a two-stage gain adjusting loop is formed.

The reducer of the second capacitor C2, i.e. the parallel capacitor of the photodiode, operates as follows. The current ipd generated by an optical signal input to the photodiode is expressed as ic2+ic1+itia. When impedance of the third resistance R3 and the first capacitor C1 connected in series to ic1 is increased, the current ic1 can be ignored. Therefore, the ipd can be expressed as ipd=ic2+itia.

For obtaining a large gain and bandwidth, the most current of the generated ipd must be itia by reducing ic2, so that the generated current must flow towards the feedback resistance. As is well known, the amount of current charged in a capacitor Δq is proportional to a capacitor size C and a voltage variation Δv between both ends, that is, it can be expressed as Δq=C*Δv. Since the C value is fixed to have a constant value, in order to reduce the amount of current charged in a capacitor, the voltage variation Δv between both ends must be reduced. That is, in order to reduce ic2, a voltage difference between Va and Vc must be reduced. The relationship between Va and Vc is described in equation (1) below. That is, the higher a frequency is, the more the voltage difference between Va and Vb is reduced. However, since the transistor TR4 is a source follower, Vc is more reduced than Vb by the rate of gm/(gm+gmb). Therefore, since a signal having the same phase as Va, but having a small amplitude is applied to Vc, ic2 value can be significantly reduced. As a result, a function is performed to reduce a value of the second capacitor C2.

$$Vb = Va \cdot \frac{sR 3}{1 + sR 3 \cdot C 1} \\ \begin{matrix}Vc = Vb \cdot \frac{gm}{gm + gmb} \\ = Va \cdot \frac{sR 3}{1 + sR 3 \cdot C 1} \cdot \frac{gm}{gm + gmb}\end{matrix} \qquad ( 1 )$$

In the above equation (1), C1 is a capacitance value of the first capacitor, s is a frequency, R3 is a resistance value of the third resistance, gm is a transconductance, and gmb is a body transconductance.

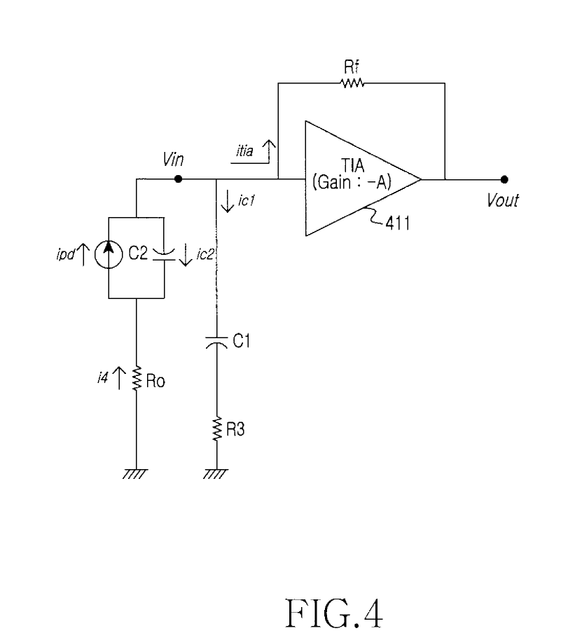

FIG. 4 shows a circuit structure diagram illustrating an equivalent circuit of a transimpedance amplifier circuit for an optical receiver according to an exemplary embodiment of the present invention. The bandwidth adjustor of the transimpedance amplifier will be described with reference to the equivalent circuit of FIG. 4 and equations (2), (3), and (4) herein below.

$$\begin{matrix}{i}_{pd} = {i}_{tia} + {i}_{c 2} + {i}_{c 1} \\ \approx {i}_{tia} + {i}_{c 2} \\ = \frac{{V}_{i n} - {V}_{out}}{{R}_{f}} + \frac{{V}_{i n} - ( 0 - {i}_{4} \cdot {R}_{0} )}{\frac{1}{{sC}_{2}}}\end{matrix} \\ ( \begin{matrix}{V}_{i n} = - \frac{{V}_{out}}{A} \\ {i}_{4} = {i}_{tia}\end{matrix} ) = - {V}_{out} [ \frac{\frac{1}{A} + 1}{{R}_{f}} + {sC}_{2} \cdot ( \frac{1}{A} + \frac{\frac{1}{A} + 1}{{R}_{f}} \cdot {R}_{0} ) ] \\ \begin{matrix}Gain = \frac{{V}_{out}}{{i}_{pd}} \\ = - \frac{A \cdot {R}_{f}}{( 1 + A ) + {sC}_{2} \cdot [ {R}_{f} + ( 1 + A ) \cdot {R}_{o} ]}\end{matrix} \qquad ( 2 )$$

In the above equation (2), A is −(Vout/Vin), s is a complex frequency (i.e. s=jw), w is 2πf, Rf is a total feedback resistance value of the transimpedance amplifier, and Ro is a resistance value of a resistance Ro of the equivalent circuit shown in FIG. 4.

Referring to equation (2), the current ipd generated from the photodiode is equal to a sum of itia, ic2, and ic1. However, as described above, since ic1 can be ignored, ipd becomes a sum of itia and ic2. After arranging this sum by a function of Vout as in equation (2) described above, an input/output transfer function is calculated by using the transimpedance amplifier gain, i.e. Vout/ipd.

Therefore, when a pole frequency, that is, a frequency below 3 dB of a gain, is calculated from the denominator, it can be expressed as equation (3) below.

$${f}_{3 dB} = \frac{1 + A}{2 \cdot π \cdot {C}_{2} \cdot [ {R}_{f} + ( 1 + A ) \cdot {R}_{o} ]} \qquad ( 3 )$$

As can be seen from equation (3) described above, 3 dB frequency depends on Rf and Ro. Generally, in existing transimpedance amplifiers, when Rf is adjusted for increasing or reducing a gain, 3 dB frequency varies inversely proportional to this. However, in the present invention, since the Ro variable is further added according to the present invention, this shortcoming can be compensated.

$$( \begin{matrix}\begin{matrix}{R}_{o} = \frac{1}{{g}_{m} + {g}_{mb}} \\ \approx \frac{1}{{g}_{m}}\end{matrix} \\ {g}_{m} = \sqrt{2 \cdot {k}^{′} \cdot {( \frac{W}{L} )}_{4} \cdot {I}_{4}}\end{matrix} ) \qquad ( 4 )$$

In the above equation (4), k′ is u*Cox, u is a mobility, Cox is a capacitance of a gate oxide film, W is a channel width of the transistor TR4, and L is a channel length of the transistor TR4.

As shown in the above equation (4), the Ro is expressed as the inverse of gm, and in order to change gm, it is effective to change a bias current i4 of TR4.

That is, when a small optical signal is input according to an exemplary embodiment of the present invention, Rf is increased because of a gain increased by the auto gain adjustor. Therefore, for preventing 3 dB frequency from excessively being reduced, it is necessary to reduce Ro. Since gm must be increased in order to reduce Ro, i4 is increased.

As described above, when a small optical signal is input, since an output of the comparator 213 is ‘Logic Low’, the third transistor TR3 and the fifth transistor TR5 are operated by turning ‘OFF’ the first transistor TR1. Therefore, on the assumption that sizes of the two transistors are equal to the second transistor TR2, the bias current i4 of the fourth transistor TR4 is determined as two times larger than the Is value by the current mirror circuit.

On the contrary, when a large optical signal is input, on the same principle as the above-mentioned description, it is necessary to increase Ro. Since gm must be reduced in order to increase Ro, i4 is reduced. In this case, in order to reduce i4, since a large optical signal has been input, the output of the comparator 213 is ‘Logic High’, the first transistor TR1 is turned ‘ON’, and a gate of the fifth transistor TR5 is applied with ‘Logic Low’, so that the fifth transistor TR5 is turned ‘OFF’, and thus is not operated. Therefore, the Is value is determined as the bias current i4 of the fourth transistor TR4 by the current mirror circuit.

Further, in addition to the above-mentioned method, in order to change Ro, a method in which a channel width W and a channel length L of a transistor are changed may be used.

As described above, according to the present invention, a range of an increase/decrease in bandwidth according to gain change can be reduce by operating the bandwidth adjustor, so that it is possible to design a transimpedance amplifier having small bandwidth change according to an intensity of an input signal.

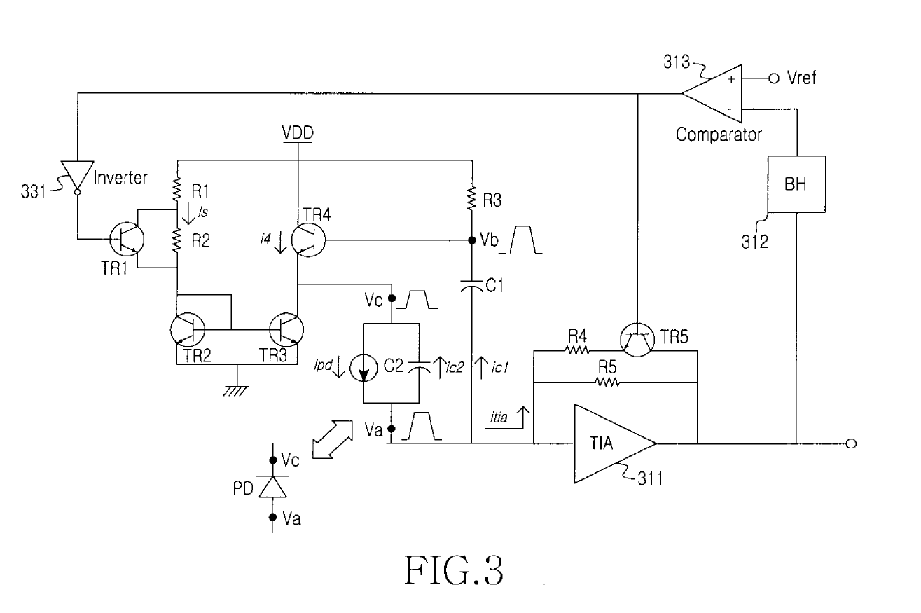

FIG. 3 shows a circuit structure diagram illustrating a transimpedance amplifier for an optical receiver according to another embodiment of the present invention.

The transimpedance amplifier circuit for the optical receiver according to another embodiment of the present invention includes: a photodiode for generating a current signal by photoelectric conversion of an input optical signal; a transimpedance amplifier 311 for converting the current signal input from the photodiode into a voltage signal; an auto gain adjustor for adjusting feedback resistances of the transimpedance amplifier 311; a photodiode parallel capacitor reducer; and a bandwidth adjustor of the transimpedance amplifier 311.

In the second exemplary embodiment shown in FIG. 3, since the photodiode parallel capacitor reducer and the auto gain adjustor are identical to those of the example shown in FIG. 2, the detailed description thereof will be omitted.

The bandwidth adjustor of the transimpedance amplifier according to another exemplary embodiment of the present invention includes: a second transistor TR2 and a third transistor TR3 included in a current mirror circuit; a first resistance R1 and a second resistance R2 connected in series with each other on a path where the current Is flows; an inverter 331 connected in serial to an Output stage of the comparator 313; and a first transistor connected in parallel to the second resistance and performing a switching operation according to an output signal of the comparator 313 through the inverter 331.

A bandwidth adjusting operation of the transimpedance amplifier for the optical receiver according to another exemplary embodiment of the present invention will now be described. In the another embodiment of the present invention, in order to generate Is, without using fixed resistances, after the first resistance is connected in serial to the second resistance, the first transistor connected to the inverter 331 is connected in parallel to the second resistance. When a large optical signal is input, the first transistor is turned ‘OFF’, and the first resistance is connected to the second resistance, so that Is is reduced. When a small optical signal is input, the first transistor is turned ‘ON’, and current flows to the first transistor through the first resistance, so that is is increased. This determined Is becomes a bias current of the fourth transistor by the current mirror circuit. Therefore, according to the present invention, since a range of an increase/decrease in bandwidth according to gain change can be reduced by the bandwidth adjustor, so that it is possible to design a transimpedance amplifier having small bandwidth change according to an intensity of an input signal.

Structures and operations of the transimpedance amplifier circuit for the optical receiver in the optical communication system according to an embodiment of the present invention can be implemented as described above. While the invention has been shown and described with reference to certain exemplary embodiments thereof, it will be understood by those skilled in the art that various changes in form and details may be made therein without departing from the spirit and scope of the invention as defined by the appended claims.

The transimpedance amplifier according to the exemplary embodiments of the present invention increases a bandwidth by reducing the parallel capacitor of the photodiode (PD), and bandwidth change insensitive to an increase/decrease in the feedback resistance value of the auto gain adjusting device can be achieved.

What is claimed is:

1. A transimpedance amplifier circuit for an optical receiver in an optical communication system, comprising:
a photodiode (PD) for receiving an input optical signal, and for generating a current signal by photoelectric conversion of the input optical signal;
a transimpedance amplifier (TIA) for converting the current signal input from the PD into a voltage signal;
an auto gain adjustor for adjusting a feedback resistance of the TIA;
a photodiode parallel capacitor reducer for reducing a parallel capacitor current of the PD; and
a bandwidth adjustor for reducing a range of an increase/decrease in bandwidth according to an increase/decrease in gain of the TIA.

2. The transimpedance amplifier circuit as claimed in claim 1, wherein the auto gain adjustor comprises:
a bottom-hold circuit connected to an output stage of the transimpedance amplifier and detecting a low level of an output signal of the transimpedance amplifier;
a comparator having two input stages, an inverted (−) input stage which receives an output signal of the bottom-hold circuit, and a non-inverted (+) input stage which receives a reference voltage Vref, and for comparing input signals of the two input stages;
a resistance R4 and a resistance R5 connected in parallel to an input and an output of the transimpedance amplifier, respectively; and
a transistor TR6 connected in series to resistance R4 and for performing a switching operation of the resistance R4 according to an output signal of the comparator.

3. The transimpedance amplifier circuit as claimed in claim 2, wherein the reference voltage comprises a predetermined comparing voltage for determining by the comparator whether an input optical signal is overloaded.

4. The transimpedance amplifier circuit as claimed in claim 2, wherein:
when an output signal of the comparator comprises a ‘Logic High’, the sixth transistor is connected, and
when the output signal of the comparator comprises a ‘Logic Low’, the sixth transistor is not connected.

5. The transimpedance amplifier circuit as claimed in claim 1, wherein the photodiode parallel capacitor reducer comprises:
a capacitor (C1) connected in series with an anode terminal of the PD;
a resistance (R3) connected in series with the capacitor C1; and
a transistor (TR4) whose collector terminal is connected to a power source, whose base terminal is connected to between the capacitor C1 and the resistance R3, and whose emitter terminal is connected to a cathode terminal of the PD.

6. The transimpedance amplifier circuit as claimed in claim 5, wherein:
said PD having two ends and comprising a current source portion ipd and a capacitive portion C2 being parallel to the current source portion, wherein a current flowing through the parallel capacitor C2 of the PD is proportional to a voltage difference between both ends of the PD; and
means for reducing a voltage difference between both ends of the PD as a frequency increases, and for reducing the current flowing through the parallel capacitive portion C2 of the PD.

7. The transimpedance amplifier circuit as claimed in claim 1, wherein the bandwidth adjustor comprises:
a transistor Tr1 for switching according to the output signal of the comparator; and
a current mirror circuit comprising transistors TR2, TR3 and TR5.

8. The transimpedance amplifier circuit as claimed in claim 7, wherein an input/output transfer function of the transimpedance amplifier circuit is defined by the following equation,
$$\begin{matrix}Gain = \frac{{V}_{out}}{{i}_{pd}} \\ = \frac{A \cdot {R}_{f}}{( 1 + A ) + {sC}_{2} \cdot [ {R}_{f} + ( 1 + A ) \cdot {R}_{o} ]} ,\end{matrix}$$
wherein A is −(Vout/Vin), s is a complex frequency (i.e. s=jw), w=2πf, Rf is a total feedback resistance value of the transimpedance amplifier, and Ro is a resistance value of a resistance Ro of an equivalent circuit.

9. The transimpedance amplifier circuit as claimed in claim 8, wherein a pole frequency below 3 dB, is defined by the following equation,
$${f}_{3 dB} = \frac{1 + A}{2 \cdot π \cdot {C}_{2} \cdot [ {R}_{f} + ( 1 + A ) \cdot {R}_{o} ]} ,$$
wherein A is −(Vout/Vin), s is a complex frequency (i.e. s=jw), w=2πf, Rf is a total feedback resistance value of the transimpedance amplifier, and Ro is a resistance value of a resistance Ro of an equivalent circuit shown in FIG. 4.

10. The transimpedance amplifier circuit as claimed in claim 9, wherein Ro is defined by the following equation,
$$( \begin{matrix}\begin{matrix}{R}_{o} = \frac{1}{{g}_{m} + {g}_{mb}} \\ \approx \frac{1}{{g}_{m}}\end{matrix} \\ {g}_{m} = \sqrt{2 \cdot {k}^{′} \cdot {( \frac{W}{L} )}_{4} \cdot {I}_{4}}\end{matrix} ) ,$$
wherein k′ is u*Cox, u is a mobility, Cox is a capacitance of a gate oxide film, W is a channel width of a transistor TR4, and L is a channel length of TR4.

11. The transimpedance amplifier circuit as claimed in claim 10, wherein the transimpedance amplifier circuit for changing Ro for reducing an increase/decrease in bandwidth according to gain change, and for changing a bias current I4 of transistor TR4 in order to change Ro.

12. The transimpedance amplifier circuit as claimed in claim 11, wherein:
when the output of the comparator is ‘Logic Low’, the bandwidth adjustor adjusts the I4 to a value twice an Is value of the current mirror circuit; and
when an Output of the comparator is a ‘Logic High’, the bandwidth adjustor adjusts I4 to have a same value as the Is value.

13. The transimpedance amplifier circuit as claimed in claim 10, wherein the transimpedance amplifier circuit changes Ro in order to reduce an increase/decrease in bandwidth according to gain change, a channel width W and a channel length L of the transistor TR4 changed in order to change Ro.

14. The transimpedance amplifier circuit as claimed in claim 1, wherein the bandwidth adjustor comprises:
a current mirror circuit comprising a transistor TR2 and a transistor TR3;
a resistance R1 and a resistance R2 connected in series with each other on a path where a current (Is) of the current mirror circuit flows;
an inverter connected in series with an output stage of the comparator; and
a transistor TR1 connected in parallel to the resistance R2 and for performing a switching operation according to an output signal of the comparator through the inverter.

15. The transimpedance amplifier circuit as claimed in claim 14, wherein:
when the comparator outputs a ‘Logic High’ signal, the bandwidth adjustor turns off the transistor TR1, and the resistance R1 is connected to R2, so that the current Is being reduced to a value lower than when a ‘Logic Low’ signal is output;
when the comparator outputs a ‘Logic Low’ signal, the bandwidth adjustor turns on the transistor TR1 and current flows through the resistance R1 and the transistor TR1, so that mirror current Is being increased more than an output of a ‘Logic High’ signal; and
a determined Is becomes I4 by the current mirror circuit.
